(19) United States
(12) Patent Application Publication
(10) Pub. No.: US 2012/0084977 A1
(43) Pub. Date: Apr. 12, 2012

(54) METHOD OF MANUFACTURING BLOCK MODULE

(75) Inventors: Seung Wook PARK, Gyunggi-do (KR); Young Do KWEON, Seoul (KR); Ju Pyo HONG, Gyunggi-do (KR); Seung Wan SHIN, Gyunggi-do (KR); Kyung Seob OH, Gyunggi-do (KR)

(73) Assignee: SAMSUNG ELECTRO-MECHANICS CO., LTD., Gyunggi-do (KR)

(21) Appl. No.: 13/268,252

(22) Filed: Oct. 7, 2011

(30) Foreign Application Priority Data
Oct. 12, 2010 (KR) 1020100099368

(51) Int. Cl. H05K 3/30

(52) U.S. Cl. 29/832

(57) ABSTRACT

Disclosed herein is a method of manufacturing a block module including: mounting an electronic part on a base substrate on which a ground terminal is formed; forming a lead frame to extend to the outside of the base substrate from the ground terminal; connecting a flexible printed circuit to a circuit layer on the base substrate; forming a mold to surround the base substrate; cutting the lead frame and exposing the cut surface of the lead frame to the outside of the mold; and forming a metal coating layer connected to the lead frame on the mold, whereby the metal coating layer is formed to surround the mold to interrupt the electromagnetic waves and the metal coating layer is connected to the ground terminal by the lead frame to make the process simple.

### CROSS REFERENCE TO RELATED APPLICATION

This application claims the benefit of Korean Patent Application No. 10-2010-0099368, filed on Oct. 12, 2010, entitled “Method of Manufacturing Block Module”, which is hereby incorporated by reference in its entirety into this application.

### BACKGROUND OF THE INVENTION

1. Technical Field

The present invention relates to a method of manufacturing a block module.

2. Description of the Related Art

Recently, a demand for multi-functional and high-speed electronic products has suddenly increased. In order to meet the demands, a semiconductor device and a block module connecting the semiconductor device with a main board has been developed at very rapid speed.

Requirements for the development of the block module are closely associated with how rapidly the block module is developed and how highly the block module is integrated. In order to satisfy these requirements, there is a need to more improve and develop the block module in view of slimness and lightness, fine circuit, excellent electrical characteristics, high reliability, high-speed signal transfer structure, or the like, of the block module.

Meanwhile, most electronic devices undergo electromagnetic interference (EMI)/electromagnetic compatibility (EMC) even though there is a slight difference therebetween. Electronic energy generated from the electronic devices may be emitted through a path of any medium to cause the interference with other devices or the electronic devices may experience the interference due to electromagnetic noises or conductive noises from the outside. The electromagnetic interference is considered as a factor that functionally disorders electronic devices and degrades circuit functions and causes the malfunction of the electronic devices.

Therefore, research into the block module capable of interrupting the electromagnetic waves has been conducted recently.

FIG. 1A is a cross-sectional view of a block module 10 according to the prior art and FIG. 1B is a plan view of the block module 10 shown in FIG. 1A. Hereinafter, the block module 10 according to the prior art will be described with reference to FIGS. 1A and 1B.

The block module 10 according to the prior art includes a circuit layer 11, a substrate 13 on which a ground terminal 12 is formed, an electronic element 14, and a flexible printed circuit (FPC) 15, and a mold 16.

The electronic element 14 is mounted on the substrate 13 and the electronic element 14 is connected to the circuit layer 11 of the substrate 13. In addition, the flexible printed circuit 15 is connected to the circuit layer 11 of the substrate 13 to electrically connect the block module 10 to the outside and the mold 16 is formed to surround the substrate 13 to protect other components.

However, the block module 10 according to the prior art does not have a device for interrupting the electromagnetic waves, which degrades the performance of the block module 10.

In addition, since a metal coating layer is connected to a ground terminal 12 by punching vias on the mold 16 for implementing a ground, even when the surface of the mold 16 is coated with metal so as to interrupt the electromagnetic waves, a process may be complicated.

### SUMMARY OF THE INVENTION

The present invention has been made in an effort to provide a method of manufacturing a block module capable of effectively interrupting electromagnetic waves.

In addition, the present invention has been made in an effort to provide a method of manufacturing a block module by a simple ground process of a metal coating layer when the metal coating layer is formed so as to interrupt electromagnetic waves.

According to a preferred embodiment of the present invention, there is a method of manufacturing a block module, including: mounting an electronic part on a base substrate on which a ground terminal is formed; forming a lead frame to extend to the outside of the base substrate from the ground terminal; connecting a flexible printed circuit to a circuit layer on the base substrate; forming a mold to surround the base substrate; cutting the lead frame and exposing the cut surface of the lead frame to the outside of the mold; and disposing a metal coating layer connected to the lead frame on the mold.

At the forming of the metal coating layer, the metal coating layer may be disposed to surround the mold.

At the forming of the lead frame, the lead frames each may extend from the ground terminals formed at four corner directions of the base substrate.

At the exposing to the outside, the cut surface of the lead frame may be co-plane with the surface exposed to the outside of the mold.

The electronic part may be an active device, a passive device, or a package substrate.

At the exposing to the outside, the cutting of the lead frame may be made by a dicing process.

At the exposing to the outside, the block module may be divided into a unit block module by the dicing process.

At the forming of the lead frame, the lead frame may be bonded to the ground terminal, having a solder layer interposed between the lead frame and the ground terminal.

At the mounting of the electronic part, the ground terminal may be an align mark.

At the exposing to the outside, the lead frame and the outside of the mold may be cut together.

### BRIEF DESCRIPTION OF THE DRAWINGS

FIGS. 1A and 1B are a cross-sectional view and a plan view of a block module according to the prior art.

FIGS. 2A to 7B are diagrams for explaining a method of manufacturing a block module according to a preferred embodiment of the present invention.

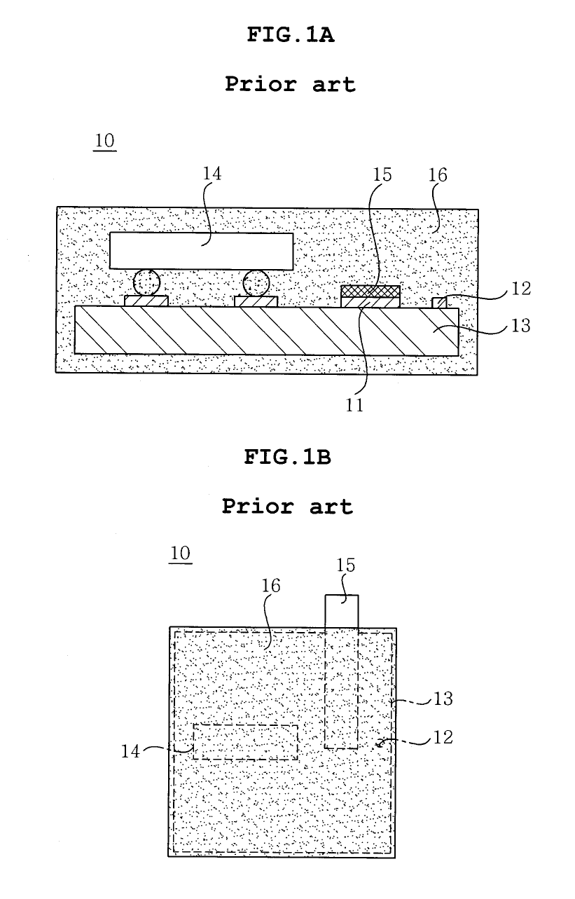

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the subject of the present invention.

Hereinafter, preferred embodiments of the present invention will be described in detail with reference to the accompanying drawings.

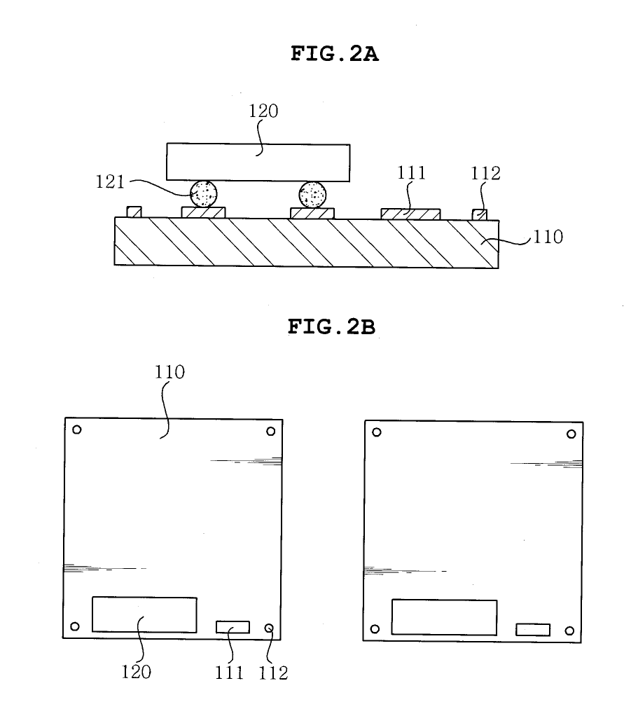

FIGS. 2A to 7B are diagrams for explaining a method of manufacturing a block module 100 according to a preferred embodiment of the present invention. In the drawings, FIG. 2A are a process cross-sectional view and FIG. 2B shows a process plan view. Hereinafter, a method of manufacturing a block module 100 according to the preferred embodiment of the present invention will be described with reference to FIGS. 2A to 7B.

First, as shown in FIGS. 2A and 2B, an electronic part 120 is mounted on the base substrate 110.

In this case, the base substrate 110, which is a basic member of the block module 100, may be a build-up layer that is configured to include multi-layer or single-layer insulating layer, circuit layer, and via. In addition, a metal layer, which is used as a heat radiation layer, may be disposed under the base substrate 110. Alternatively, the base substrate 110 may be a ceramic substrate such as a high temperature co-fired ceramic (HTCC), a low temperature co-fired ceramic (LTCC), or the like. Hereinafter, a circuit layer 111 connected to a flexible printed circuit 140 and ground terminals 112 connected to lead frames 130 may be disposed on an uppermost layer, a lowermost layer, or an intermediate layer of the base substrate 110. In this configuration, the circuit layer 111 serves to transfer and process various electrical signals within the block module 100 and the ground terminal 112 may be connected to a ground area within the block module 100. In addition, the ground terminal 112 may be disposed, for example, at four corners of the base substrate 110, respectively, so as to be used as an align mark. In addition, the circuit layer 111 and the ground terminal 112 may be made of a conductive metal such as, for example, gold, silver, copper, nickel, or the like.

In addition, the electronic part 120, which is a part mounted on the base substrate 110, may be electrically connected to the circuit layer 111 disposed on the base substrate 110 by, for example, a solder ball 121, a wire, or the like. In this case, the electronic part 120 may be, for example, an active device such as a semiconductor device, or the like, a passive device such as a capacitor, an inductor, or the like, or a package substrate in a type in which a semiconductor device, or the like, is mounted on a substrate, wherein at least one of the electronic parts may be mounted on the base substrate 110. Further, the electronic part 120 may be mounted by, for example, a surface mount technology (SMT). In this case, the ground terminal 112 may serve as an align mark.

Meanwhile, FIG. 2B shows a case in which two unit block modules 100 are manufactured together, but a case in which one or at least three unit block modules 100 may be manufactured together.

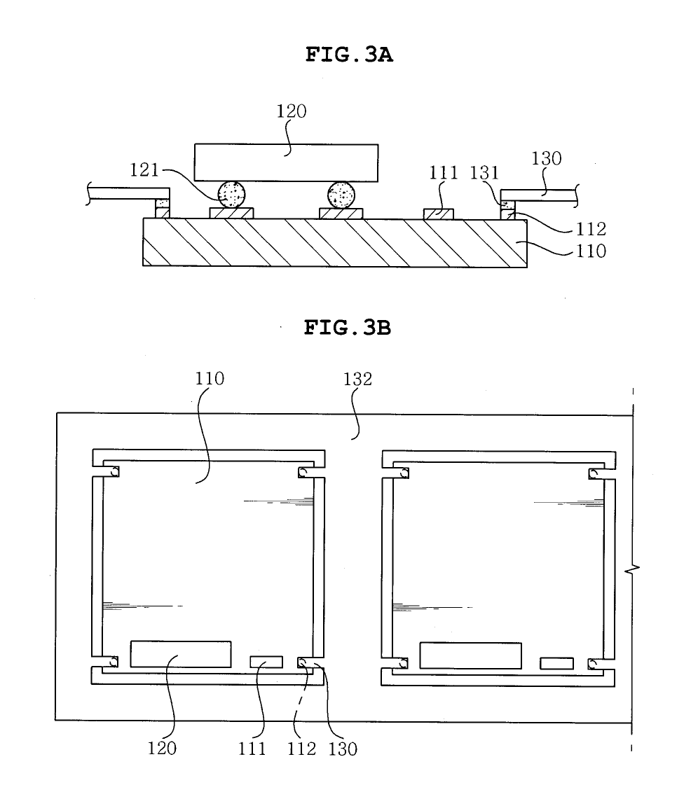

Next, as shown in FIGS. 3A and 3B, the lead frames 130 are disposed to extend to the outside of the base substrate 110 from the ground terminals 112.

In this configuration, the lead frame 130 may be bonded to the ground terminal 112, having a solder layer 131 interposed therebetween. In addition, the lead frame 130 may extend to the outside of the base substrate 110 from the ground terminal 112. Therefore, an end of the lead frame 130 may be protruded from the base substrate 110. In addition, the lead frame 130, which is made of a conductive metal, may electrically connect the metal coating layer 160 to the ground terminal 112, which are described below.

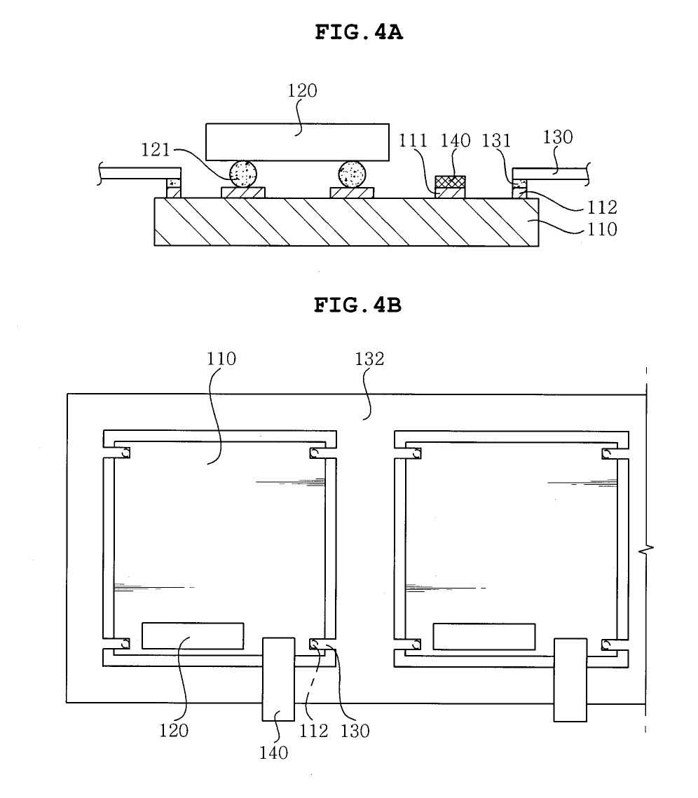

Next, as shown in FIGS. 4A and 4B, a flexible printed circuit 140 is connected to the circuit layer 111 on the base substrate 110.

In this configuration, the flexible printed circuit 140, which is a member electrically connecting the base substrate 110 to an external electronic part, or the like, may be directly connected to the circuit layer 111 on the base substrate 110 or may be connected thereto via a separate solder layer. In addition, the lead frame 130 is connected to the ground terminal 112, but the flexible printed circuit 140 is not connected to the ground terminal 112 but may be connected to only the circuit layer 111 on the base substrate 110.

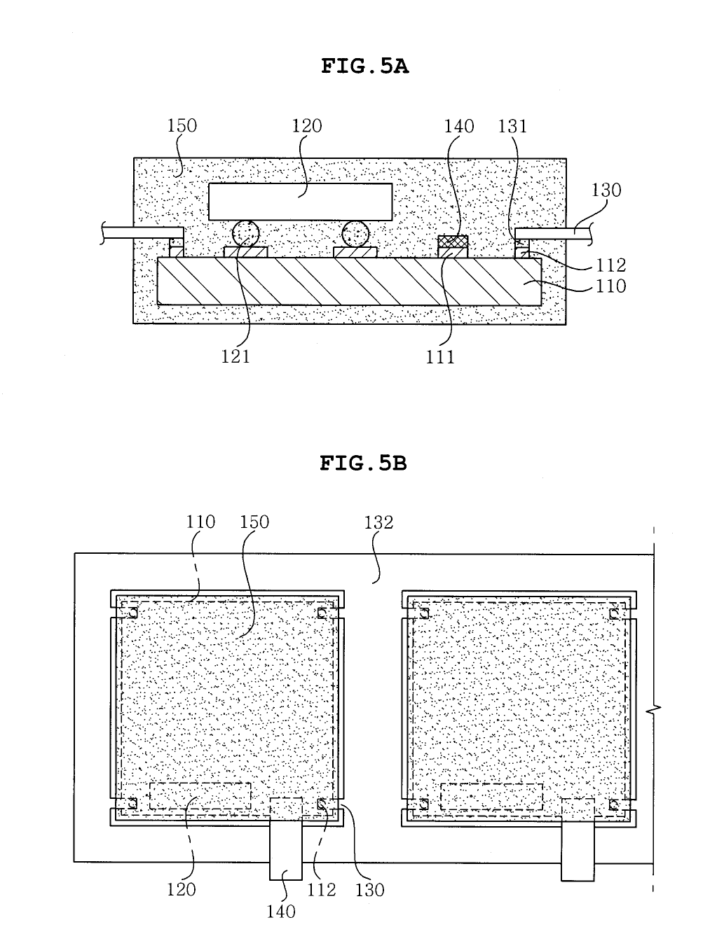

Next, as shown in FIGS. 5A and 5B, a mold 150 is formed to surround the base substrate 110.

In this case, the mold 150 may be formed to surround the entire surface of the base substrate 110 and may be formed to surround a part of the lead frame 130 Therefore, the mold 150 may protect the circuit layer 111 or the electronic part 120 formed on the base substrate 110 from external impact. The mold 150 may be made of, for example, epoxy mold compound (EMC) or silicon gel.

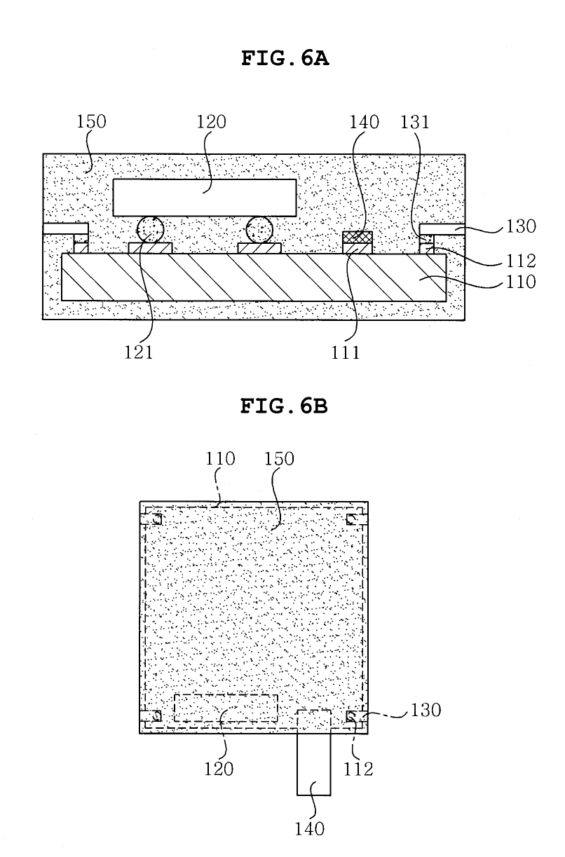

Next, as shown in FIGS. 6A and 6B, the lead frame 130 is cut and then, the cut surface of the lead frame 130 is exposed to the outside of the mold 150.

In this case, the cut surface of the lead frame 130 is exposed to the outside of the mold 150 and the cut surface of the lead frame 130 and the surface exposed to the outside of the mold 150 may be a co-plane. In addition, although FIGS. 6A and 6B show a case in which only the lead frame 130 is cut, the cut surface of the lead frame 130 may be exposed to the outside of the mold 150 by cutting a part of the mold 150.

Meanwhile, the dicing process of the lead frame 130 or the lead frame 130 and the mold 150 may be performed by a dicing process and each unit block module may be separately divided from the lead frame body 132 by the dicing process. In this case, the plurality of block modules 100 may be manufactured by one-time manufacturing process, thereby improving the productivity.

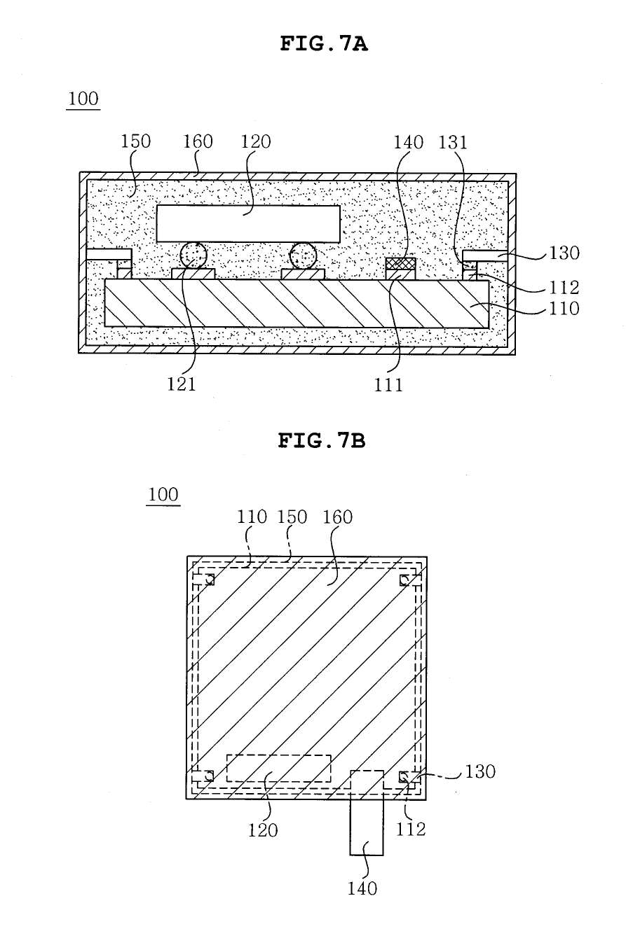

Next, as shown in FIGS. 7A and 7B, the metal coating layer 160 is disposed.

In this case, the metal coating layer 160 may be connected to the cut surface of the lead frame 130 and formed to surround the mold 150. Further, the metal coating layer 160 may be formed by coating the conductive coating and may be disposed to surround the entire surface of the mold 150. In addition, the metal coating layer 160 may be formed by a sputtering method, a deposition method, a plating method, or the like. Further, the metal coating layer 160 is formed to surround the mold 150, thereby improving the mechanical strength of the block module 100.

Meanwhile, the metal coating layer 160 is electrically connected to the ground terminal 112 through the lead frame 130, wherein the metal coating layer 160 may also be a ground state. Therefore, the metal coating layer 160 may interrupt harmful electromagnetic waves generated from the electronic part 120, or the like, or harmful electromagnetic waves generated from the outside. That is, the electromagnetic interference (EMI)/electromagnetic compatibility (EMC) phenomenon may be interrupted. Meanwhile, the metal coating layer 160 may be relatively simply ground by the lead frame 130.

The block module 100 according to the preferred embodiment of the present invention as shown in FIGS. 7A and 7B is manufactured by the above-mentioned manufacturing process.

As set forth above, the preferred embodiment of the present invention forms the metal coating layer connected to the ground so as to surround the mold, thereby effectively interrupting the electromagnetic waves from the inside and the outside.

In addition, the preferred embodiment of the present invention connects the ground terminal in the block module with the metal coating layer using the lead frame, thereby simplifying the ground process of the metal coating layer.

Further, the preferred embodiment of the present invention forms the metal coating layer on the surface of the mold, thereby improving the mechanical strength of the block module.

Further, the preferred embodiment of the present invention manufactures the block module in a plural unit by one-time manufacturing process, thereby improving the productivity.

Although the preferred embodiments of the present invention have been disclosed for illustrative purposes, they are for specifically explaining the present invention and thus a method of manufacturing a block module according to the present invention is not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A method of manufacturing a block module, comprising:
mounting an electronic part on a base substrate on which a ground terminal is formed;
forming a lead frame to extend to the outside of the base substrate from the ground terminal;
connecting a flexible printed circuit to a circuit layer on the base substrate;
forming a mold to surround the base substrate;
cutting the lead frame and exposing the cut surface of the lead frame to the outside of the mold; and
disposing a metal coating layer connected to the lead frame on the mold.

2. The method as set forth in claim 1, wherein at the forming of the metal coating layer, the metal coating layer is disposed to surround the mold.

3. The method as set forth in claim 1, wherein at the forming of the lead frame, the lead frames each extend from the ground terminals formed at four corner directions of the base substrate.

4. The method as set forth in claim 1, wherein at the exposing to the outside, the cut surface of the lead frame is co-plane with the surface exposed to the outside of the mold.

5. The method as set forth in claim 1, wherein the electronic part is an active device, a passive device, or a package substrate.

6. The method as set forth in claim 1, wherein at the exposing to the outside, the cutting of the lead frame is made by a dicing process.

7. The method as set forth in claim 1, wherein at the exposing to the outside, the block module is divided into a unit block module by the dicing process.

8. The method as set forth in claim 1, wherein at the forming of the lead frame, the lead frame is bonded to the ground terminal, having a solder layer interposed between the lead frame and the ground terminal.

9. The method as set forth in claim 1, wherein at the mounting of the electronic part, the ground terminal is an align mark.

10. The method as set forth in claim 1, wherein at the exposing to the outside, the lead frame and the outside of the mold are cut together.
